(19) United States
(12) Patent Application Publication
(10) Pub. No.: US 2021/0225819 A1
(43) Pub. Date: Jul. 22, 2021

(54) Production Method of a Decorative Light String

(71) Applicant: Nanning City Hong Cai Illuminations Technology Company Limited, Nanning City (CN)

(72) Inventor: Faquan Liang, Nanning City (CN)

(21) Appl. No.: 16/782,885

(22) Filed: Feb. 5, 2020

(30) Foreign Application Priority Data
Jan. 16, 2020 (CN) 202010045619.X

(51) Int. Cl. H01L 25/13; H01L 33/62; H01L 33/52; H01L 25/075

(52) U.S. Cl. CPC H01L 25/13; H01L 33/62; H01L 2933/005; H01L 25/0753; H01L 2933/0066; H01L 33/52

(57) ABSTRACT

A production method of a decorative light string includes the steps of: soldering a plurality of SMD beads or chip equidistantly onto a lead wire according to a sequential order; filling an encapsulation glue into a plurality of casings; putting the SMD beads or chips soldered onto the lead wire into the encapsulation glue filled into the casings according to a sequential order and then into an oven until the encapsulation glue is cured; and assembling the SMD beads or chips encapsulated into the casing with a base. This method requires no stamped electroplated parts to reduce the production cost significantly and satisfy the increasingly higher requirements for modern industries and the production of decorative light strings.

### FIELD OF INVENTION

The present invention relates to the technical field of lighting appliances, in particular to a production method of a decorative light string.

### BACKGROUND OF INVENTION

### Description of the Related Art

Due to the variety of stylish shapes and colorful flashing lights, decorative light strings can provide a decorative lighting effect at night and have become the first choice for people to use them in festivals in order to add festival atmosphere.

In general, a conventional production method of a decorative light string includes the steps of: putting a plurality of LED chips into a plurality of lamp cups of a support stand respectively; soldering the chips to connect adjacent LED chips serially; putting the support stand downwardly into a forming mold which is filled with an encapsulation glue; putting the mold into an oven until the encapsulation glue is cured; removing the support stand and installing the manufactured LED beads into a base; and finally assembling the casing with the base. Since the conventional method requires the use of the support stand which is a stamped electroplated part with a relatively high production cost, the conventional method cannot satisfy the increasingly higher requirements of modern industries and the production of decorative lighting string.

Obviously, the conventional method requires improvements.

### SUMMARY OF THE INVENTION

Therefore, it is a primary objective of this invention to overcome the drawbacks of the conventional light string by providing a low-cost method to produce decorative light strings.

To achieve the aforementioned and other objectives, the present invention provides a production method of a decorative light string comprising the following steps (a) to (d):

(a) Solder a plurality of SMD beads or chip equidistantly onto a lead wire according to a sequential order.

(b) Filling an encapsulation glue into a plurality of casings.

(c) Put the SMD beads or chips soldered onto the lead wire into the encapsulation glue which is filled into the casings according to a sequential order and then into an oven until the encapsulation glue is cured.

(d) Assemble the SMD beads or chips encapsulated into the casing with a base.

Compared with the prior art, the present invention has the following advantageous effects:

The method of the invention requires no stamped electroplated parts, so that the production cost can be reduced significantly and the increasingly higher requirements for modern industries and the production of decorative light strings can be satisfied.

### DESCRIPTION OF THE PREFERRED EMBODIMENTS

To make it easier for our examiner to understand the objective of the invention, its structure, innovative features, and performance, we use a preferred embodiment together with the attached drawings for the detailed description of the invention.

The present invention is directed to a production method of a decorative light string, comprising the following steps (a) to (d):

(a) Solder a plurality of SMD beads or chips equidistantly onto a lead wire according to a sequential order. Wherein, the anode and cathode of the SMD beads or chips are electrically coupled to the lead wire.

(b) Fill an encapsulation glue into a plurality of casings. Wherein, the glue is filled into the casings by a dispenser.

(c) Put the SMD beads or chips soldered onto the lead wire into the glue contained in the casing according to a sequential order, and then into an oven until the encapsulation glue is cured.

(d) Assemble the SMD bead or chip encapsulated in the casing with a base to produce a light string.

Since the SMD bead or chip is encapsulated into the casing directly, and then assembled with the base, therefore the invention requires no stamped electroplated parts and reduces the production cost significantly.

In summation, the present invention overcomes the drawbacks of the prior by producing a production method with the features of simple manufacturing process, easy implementation, and low production cost.

While the invention has been described by means of specific embodiments, numerous modifications and variations could be made thereto by those skilled in the art without departing from the scope and spirit of the invention set forth in the claims.

What is claimed is:

1. A production method of a decorative light string, comprising the steps of:
(a) soldering a plurality of SMD beads or chip equidistantly onto a lead wire according to a sequential order;
(b) filling an encapsulation glue into a plurality of casings;
(c) putting the SMD beads or chips soldered onto the lead wire into the encapsulation glue which is filled into the casings according to a sequential order and then into an oven until the encapsulation glue is cured; and
(d) assembling the SMD beads or chips encapsulated into the casing with a base.
